(19) United States
(12) Patent Application Publication
(10) Pub. No.: US 2018/0074097 A1
(43) Pub. Date: Mar. 15, 2018

(54) Power-Outage Sensing Apparatus

(71) Applicant: RVA Lighting & Masts Inc., Toronto (CA)

(72) Inventor: James Fess, Toronto (CA)

(21) Appl. No.: 15/702,247

(22) Filed: Sep. 12, 2017

Related U.S. Application Data
(60) Provisional application No. 62/393,178, filed on Sep. 12, 2016.

(51) Int. Cl. G01R 19/155; G08B 21/18; G01R 31/40; G01R 31/333

(52) U.S. Cl. CPC G01R 19/155; G01R 31/3333; G01R 31/40; G08B 21/185

(57) ABSTRACT

The apparatus is for use with a grid-linked facility and an alarm functionality. The grid-linked facility is of the type having a building containing an electrical load; and a breaker connected to the load and to the grid. The alarm functionality includes electronics adapted to produce information, the information being responsive to the availability of grid power downstream of the breaker; and transmission functionality adapted to receive information and to send received information beyond the building, the transmission functionality being coupled in use to the electronics for the receipt of information therefrom. The apparatus comprises a sensing functionality disposed in use upstream of the breaker; and circuitry coupled in use to the sensing functionality and the transmission functionality to deliver information associated with the availability of grid power upstream of the breaker to the transmission functionality.

### RELATED APPLICATION DATA

This application claims the benefit of priority of U.S. Provisional Patent Application Ser. No. 62/393,178, filed Sep. 12, 2016, and titled “Power-Outage Sensor,” which is incorporated by reference herein in its entirety.

### FIELD OF THE INVENTION

The invention relates to the field of unmanned facilities such as transmission towers.

### BACKGROUND

Unmanned facilities are often provided in remote locations. Often, small structures form part of the facilities and expensive electronic equipment and batteries are secured in the structures. The structures are commonly climate-controlled, since, inter alia, the contents can deteriorate or fail at elevated temperatures. The climate control, as well as the internal electronics, are typically powered from the grid. Grid power is known to fail. It is known to monitor the electricity entering the structure from the grid, so that, if the grid power fails, the power supplier can be notified. Normally, the operator of the unmanned facility is required to send a technician to the site to confirm that the breaker to the grid is in good order; the power supplier often refuses to send a technician on the basis of a power outage behind the breaker since the power outage may be a result of a tripped or failed breaker rather than a loss of power to the breaker. The need to send a technician to check the breaker in the event of a power loss adds cost to the operator of the unmanned facility and can add to service downtime. As well, the delay associated with an intermediate technician attendance can sometimes result in equipment failure.

### SUMMARY OF THE DISCLOSURE

Forming one aspect of the invention is power outage sensing apparatus for use with a grid-linked facility and an alarm functionality. The grid-linked facility is of the type having: a building containing an electrical load; and a breaker connected to the load and to the grid. The alarm functionality includes: electronics adapted to produce information, the information being responsive to the availability of grid power downstream of the breaker; and transmission functionality adapted to receive information and to send received information beyond the building, the transmission functionality being coupled in use to the electronics for the receipt of information therefrom.

This apparatus comprises: a sensing functionality disposed in use upstream of the breaker; and circuitry coupled in use to the sensing functionality and the transmission functionality to deliver information associated with the availability of grid power upstream of the breaker to the transmission functionality.

According to another aspect, the circuitry can be coupled in use to the sensing functionality, the electronics and the transmission functionality and be adapted to deliver information to the transmission functionality responsive to the loss of grid power upstream of the breaker that occurs before loss of power downstream of the breaker.

According to another aspect, the circuitry can be coupled in use to the sensing functionality, the electronics and the transmission functionality and be adapted to deliver information to the transmission functionality responsive to the loss of grid power that occurs before the main power disconnect of the building.

The apparatus can, according to another aspect of the invention, form part of a consumer package. This consumer package further comprises battery storage that is coupled in use to the grid downstream of the breaker to be charged when the grid is active.

In this consumer package, the sensing functionality can comprise a non-contact voltage sensor adapted to sense EMI associated with the availability of grid power upstream of the breaker.

In other aspect, the apparatus forms part of a consumer package which comprises transmission functionality adapted to receive information and to send received information beyond the facility and wherein the circuitry is coupled to the sensing functionality and the transmission functionality and be adapted to deliver information to the transmission facility responsive to the absence of grid power upstream up the breaker.

According to another aspect, this consumer package can further comprise battery storage that is coupled in use to the grid downstream of the breaker to be charged when the grid is active.

According to yet another aspect, in this consumer package, the transmission functionality can be adapted to send information over a cellular network.

### BRIEF DESCRIPTION OF THE DRAWINGS

For the purpose of illustrating the invention, the drawings show aspects of one or more embodiments of the invention. However, it should be understood that the present invention is not limited to the precise arrangements and instrumentalities shown in the drawings, wherein:

FIG. 1 is a schematic diagram of a first embodiment of the power outage sensing apparatus;

FIG. 2 is a schematic diagram of a second embodiment of the power outage sensing apparatus;

FIG. 3 is circuit diagram showing certain aspects of the first embodiment of FIG. 1;

FIG. 4 is a circuit diagram showing additional aspects of the first embodiment of FIG. 1;

FIG. 5 is a circuit diagram showing yet additional aspects of the first embodiment of FIG. 1; and

FIG. 6 is a circuit diagram showing even additional aspects of the first embodiment of FIG. 1.

### DETAILED DESCRIPTION

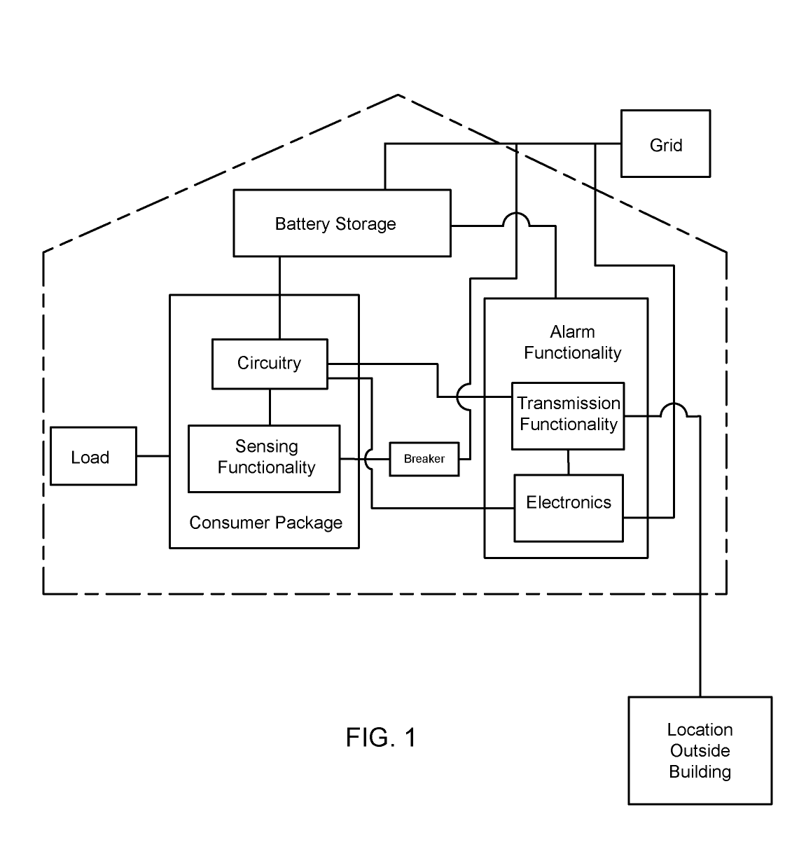

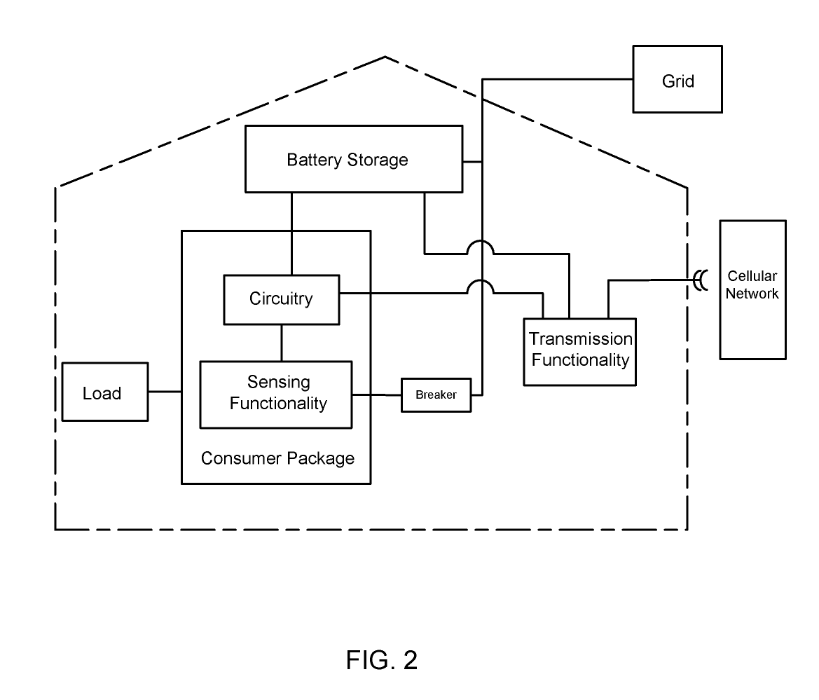

Two exemplary embodiments of the invention are hereinafter described, as illustrated schematically in FIGS. 1 and 2.

Each embodiment is defined by a commercial package and is utilized with a grid-linked facility having: a building containing an electrical load; and a breaker connected to the load and to the grid.

Referring to FIG. 1, the first embodiment is used with an alarm functionality that includes: electronics adapted to produce information, the information being responsive to the availability of grid power downstream of the breaker; and transmission functionality adapted to receive information and to send received information beyond the building, the transmission functionality being coupled in use to the electronics for the receipt of information therefrom.

This consumer package comprises:

a sensing functionality disposed in use upstream of the breaker and defined at least in part by a non-contact voltage sensor;

circuitry coupled in use to the sensing functionality, the transmission functionality and the electronics and adapted to deliver information to the transmission functionality responsive to the loss of grid power upstream of the breaker before loss of power downstream of the breaker, specifically, before the main power disconnect of the building; and

battery storage that is coupled in use to the grid downstream of the breaker to be charged when the grid is active.

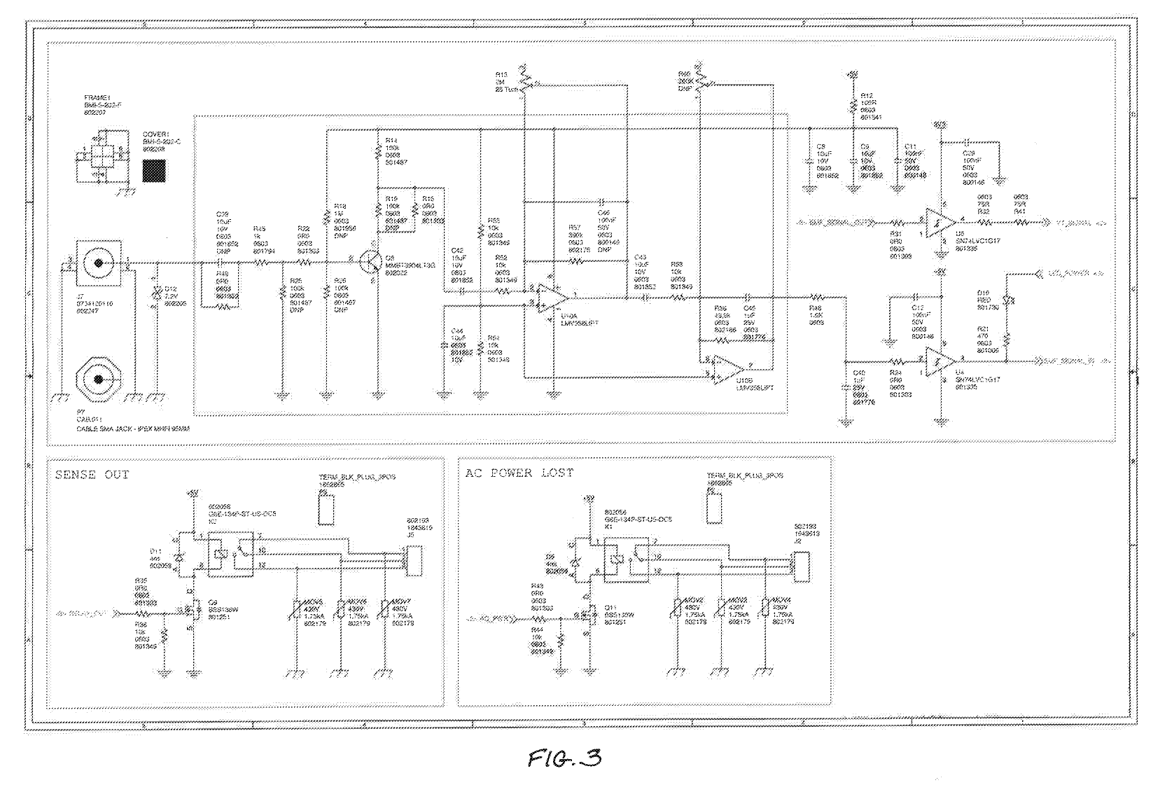

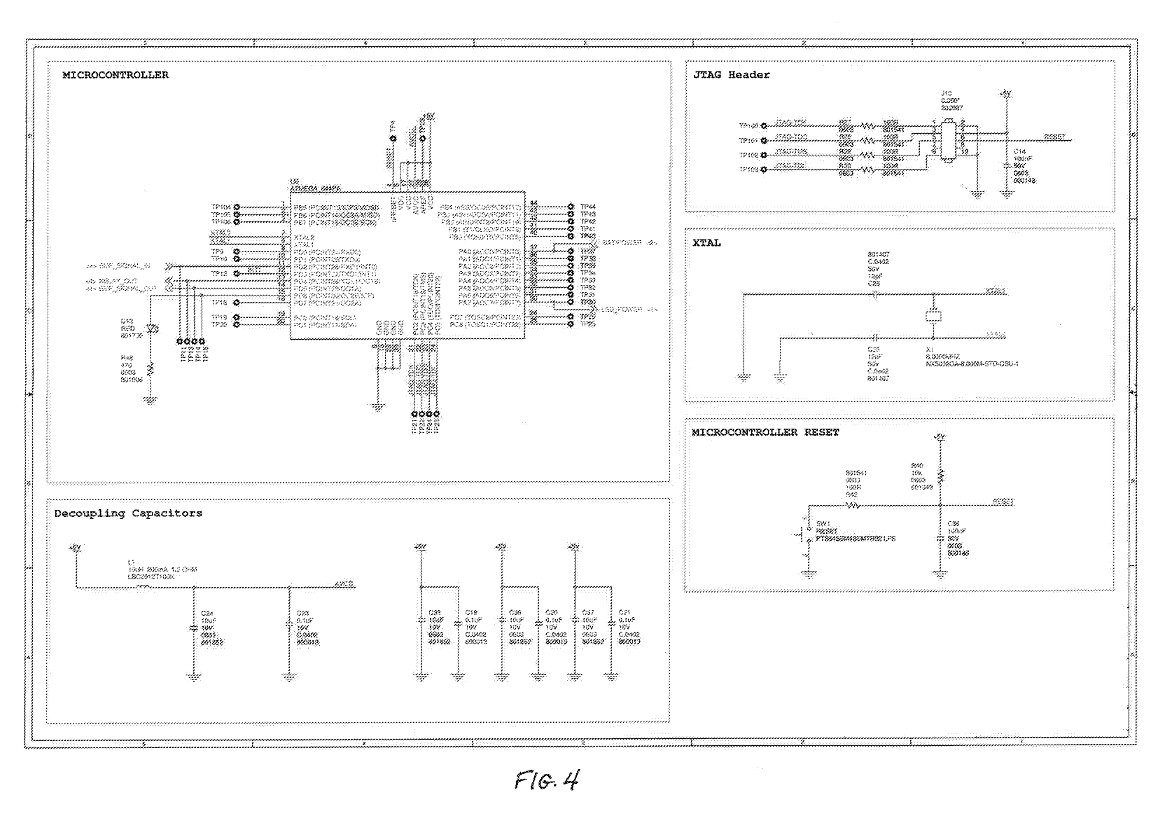

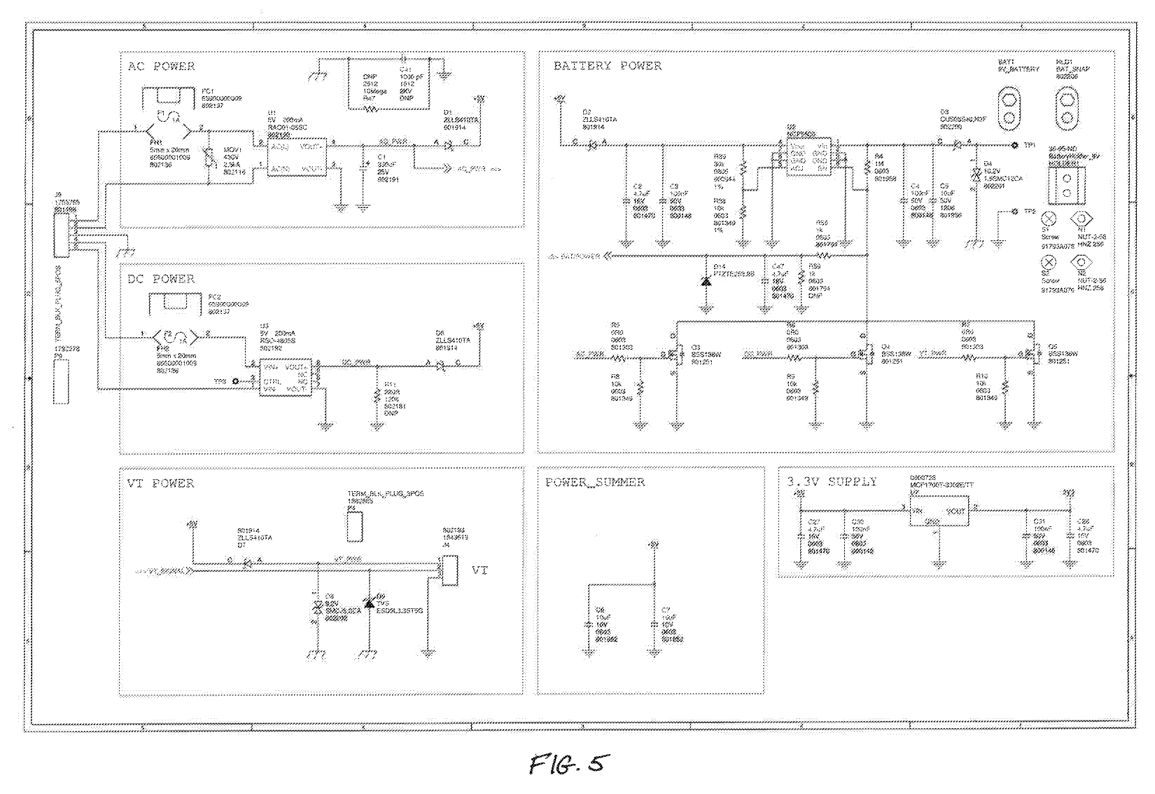

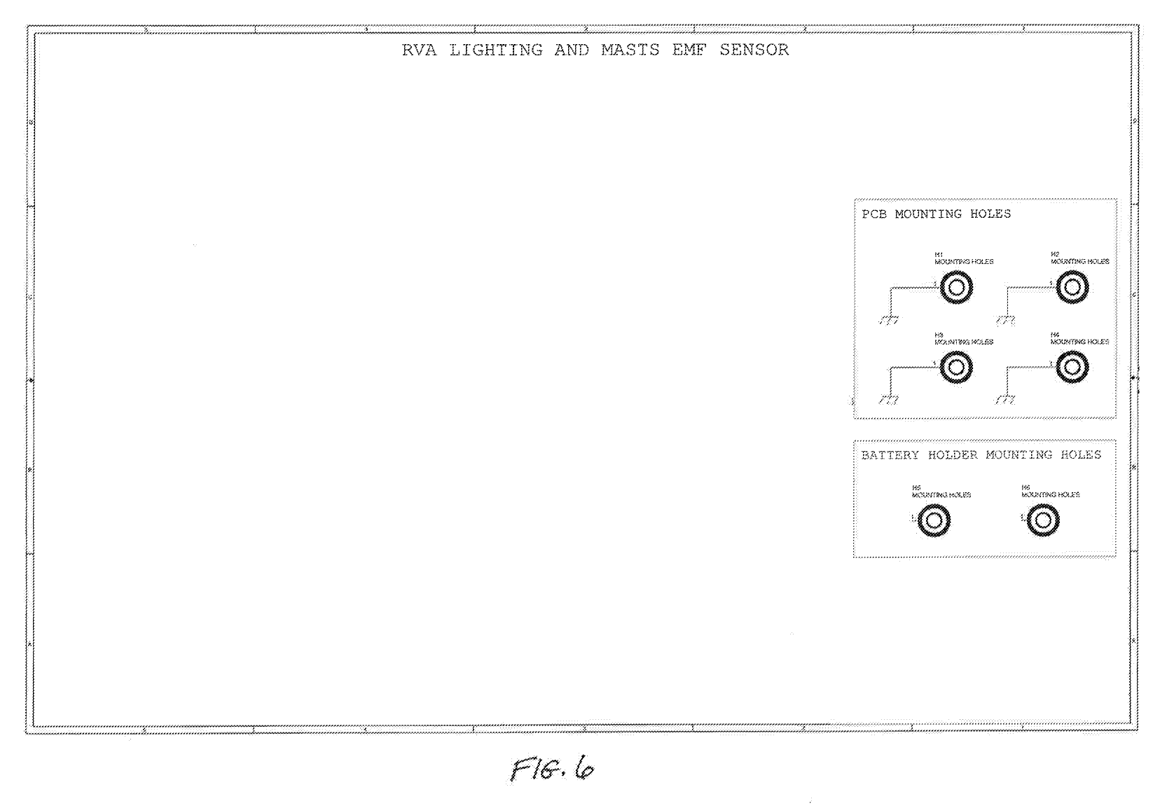

FIGS. 3-6 show more detailed aspects of the first embodiment, which are known to be useful in association with unmanned facilities having a wide variety of alarm management systems and a wide variety of power feeds.

With reference go FIG. 2, the second embodiment comprises:

a sensing functionality disposed in use upstream of the breaker;

transmission functionality adapted to receive information and to send received information using a cellular network beyond the facility;

circuitry coupled in use to the sensing functionality and the transmission functionality and is adapted to deliver information to the transmission functionality responsive to the loss of grid power upstream of the breaker; and

battery storage that is coupled in use to the grid downstream of the breaker to be charged when the grid is active.

In both embodiments, the operator of the unmanned facility is provided with information indicative of the loss of grid, rather than facility, power, and can therefore arrange for the power provider to troubleshoot the grid power loss.

The second embodiment, by virtue of the inclusion of a cellular transceiver and the reliance upon the non-contact voltage sensor, only, is more costly and less reliable than the former, but can be useful in situations wherein the unmanned facility is not already protected by an alarm service.

Whereas two specific embodiments are described, variations are possible. Accordingly, the invention should be understood to be limited only by the accompanying claims, purposively construed.

Whereas a single embodiment is herein shown and described, variations are possible. Accordingly, the invention should be understood to be limited only by the accompanying claims, purposively construed.

Exemplary embodiments have been disclosed above and illustrated in the accompanying drawings. It will be understood by those skilled in the art that various changes, omissions and additions may be made to that which is specifically disclosed herein without departing from the spirit and scope of the present invention.

What is claimed is:

1. Apparatus for use with a grid-linked facility and an alarm functionality,
the grid-linked facility being of the type having:
a building containing an electrical load; and
a breaker connected to the load and to the grid,
the alarm functionality including:
electronics adapted to produce information, the information being responsive to the availability of grid power downstream of the breaker; and
transmission functionality adapted to receive information from the electronics and to send received information beyond the building, the transmission functionality being coupled in use to the electronics for the receipt of information therefrom,
the apparatus comprising:
a sensing functionality disposed in use upstream of the breaker; and
circuitry coupled in use to the sensing functionality and the transmission functionality to deliver information associated with the availability of grid power upstream of the breaker to the transmission functionality.

2. Apparatus according to claim 1, wherein the circuitry is coupled in use to the sensing functionality, the electronics and the transmission functionality and is adapted to deliver information to the transmission functionality responsive to the loss of grid power upstream of the breaker before loss of power downstream of the breaker.

3. Apparatus according to claim 2, wherein the circuitry is coupled in use to the sensing functionality, the electronics and the transmission functionality and is adapted to deliver information to the transmission functionality responsive to the loss of grid power before the main power disconnect of the building.

4. A consumer package comprising:
apparatus according to claim 3; and
battery storage that is coupled in use to the grid downstream of the breaker to be charged when the grid is active.

5. Apparatus according to claim 4, wherein the sensing functionality comprises a non-contact voltage sensor adapted to sense EMI associated with the availability of grid power upstream of the breaker.
